(19) United States
(12) Patent Application Publication
(10) Pub. No.: US 2009/0039524 A1
(43) Pub. Date: Feb. 12, 2009

(54) METHODS AND APPARATUS TO SUPPORT AN OVERHANGING REGION OF A STACKED DIE

(75) Inventors: Charles A. Odegard, McKinney, TX (US); Richard W. Arnold, McKinney, TX (US); Marvin W. Cowens, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/835,909

(22) Filed: Aug. 8, 2007

(51) Int. Cl. H01L 23/48; H01L 21/58

(52) U.S. Cl. 257/777; 438/109; 257/E21.505; 257/E23.01

(57) ABSTRACT

Methods and apparatus to support an overhanging region of stacked die are disclosed. A disclosed method comprises bonding a first die onto a substrate, placing a support element on the substrate; and bonding a second die onto the first die, wherein the second die overhangs at least one edge of the first die and the support element is positioned to limit bending of the second die.

### TECHNICAL FIELD

The present disclosure pertains to assembly of integrated circuits and, more particularly, to methods and apparatus to support an overhanging region of a stacked die.

### BACKGROUND

Consumers now demand more processing power from electronics such as cellular phones, personal digital assistants, computers, etc. However, more processing power means additional integrated circuits, which require more physical space. One method to reduce physical space is to stack the integrated circuits on top of each other. However, to stack the integrated circuits, the thickness of the die must be reduced, for example, to thicknesses measured in micrometers, which makes the die flexible.

### SUMMARY

Example methods and apparatus to support an overhang region of a stacked die of an integrated circuit are described. In some example methods, a first die is attached to a substrate, a support element is placed near the corner or the edge of the upper die that will overhang the first die, and a second die is bonded on top of the first die so that it overhangs the first die on the corner or edge. During assembly operations, the support element prevents the overhanging edge of the second die from bending down and damaging the components of the integrated circuit.

In some examples, the support element is made by creating a stack of gold bumps on the substrate.

In other examples, to allow the operation of assembly tools, the support element is bent over and the top of the support element is attached to a pad on substrate. Before placing the second die, the top of the support element is unattached from the pad and the support element returns to its initial position.

In other examples, the support element is an elastic material that allows assembly tools to operate freely. Before placing the second die, the substrate is heated to a transition temperature that causes the support element to become inelastic and rigid.

### BRIEF DESCRIPTION OF THE DRAWINGS

FIG. 1 is an illustration of an example integrated circuit with stacked die.

FIG. 2 is an illustration of an example integrated circuit with stacked die with an overhang edge and a support element.

FIG. 3 is a diagram representing an example method to assemble an integrated circuit with an example support element.

FIG. 4 is another diagram representing an example method to assemble an integrated circuit with a support element.

FIG. 5 is another diagram representing an example method to assemble an integrated circuit with a support element.

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

In view of the foregoing, methods and apparatus to support an overhang region of a stacked die are disclosed herein. Although the following disclosure focuses on example integrated circuits with two stacked die, the description is not limited to integrated circuits with two stacked die. On the contrary, the disclosure extends to any integrated circuit with any number of stacked die and any number of overhang edges, corners, or both.

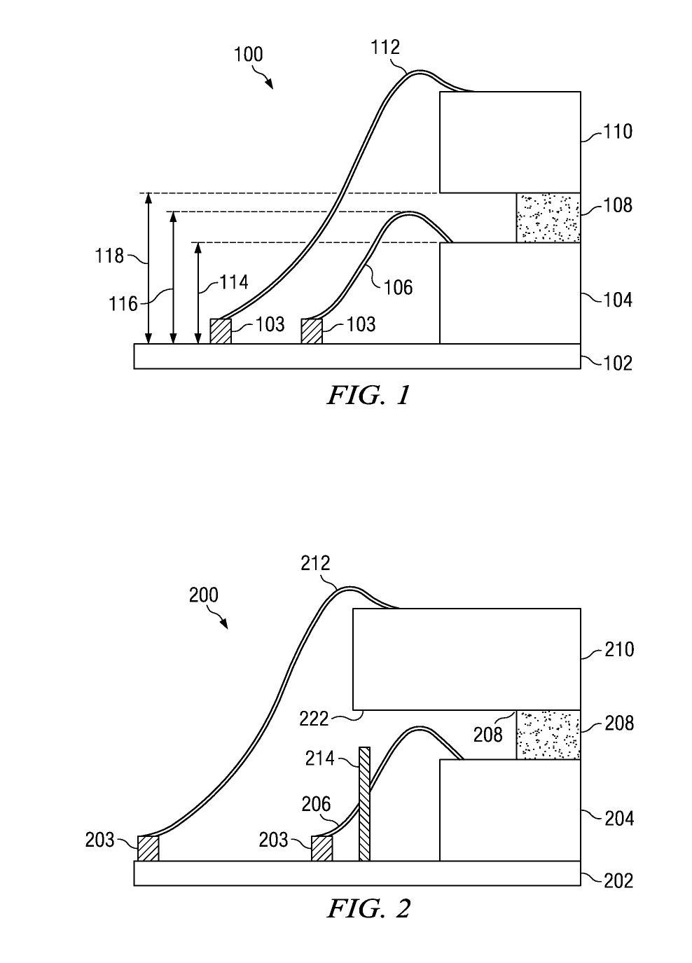

FIG. 1 is an illustration of an example integrated circuit (IC) in a stacked die configuration. The example IC 100 includes a substrate 102 with a plurality of pads 103 for bonding. The substrate may be implemented by any material that can accept the first die by any attaching technique (e.g., eutectic bond, epoxy, solder, etc.). The pads 103 of the illustrated example are regions that allows bonding of wire bonds, die, and other elements associated with the IC 100.

To assemble the example IC 100 of FIG. 1, a first die 104 is attached the substrate 102. After attaching the first die, the first die 104 is probed to determine if the die is functional. After probing, to couple the first die 104 to the pads 103, the bond wires 106 are connected from the top of the first die 104 to the pads 103. The bond wires 106 may be implemented by any type of material (e.g., aluminum, gold, copper, etc.) and may be wire bonded using any technique (e.g., bell bond, wedge bond, etc.).

In some examples, after the first die 104 is attached, a spacer 108 is applied on top of the first die 104. As illustrated in the example of FIG. 1, the spacer 108 creates a space between the first die 104 and a second die 110 for the bond wires 106. The spacer may be implemented by an example material such as silicon or a special non-conducting tape. The second die 110 is attached to the top of the spacer 108 using any attaching technique. Once the second die 110 is attached, the second die 110 is probed to determine if the die is functional. If the second die 110 is functional, the second die 110 is wire bonded with a plurality of wire bonds 112 from the top of the second die 110 to the pads 103.

In the example of FIG. 1, an example bond wire 106 loops above a minimum loop height 114, which is the distance from the surface of the substrate 102 to the upper surface of the first die 104. The loop height 116 of the bond wire 106 is the distance from the substrate 102 to the peak of the bond wire 106. The maximum loop height 118 of the bond wire 106 is the distance from the surface of the substrate 102 to the top of the spacer 108. If the bond wire 106 has a loop height exceeding the maximum height 118, the bond wire 106 will be damaged during bonding and probing operations associated with the second die 110.

As described above, the die are thin and flexible and, thus, common operations associated with integrated circuit test and assembly (e.g., die bonding, die attaching, wire bonding, probe testing, etc.) may place downward pressure on the second die 110, causing the second die 110 to bend downward. When the second die 110 bends down, it is possible that the bottom side of the second die 110 may contact the wire bonds 106 of the first die 104, thereby causing electrical failure, reliability failure, or both to the IC 200. Additionally, excessive bending of the second die 110 may also lead to bonding failure, electrical failure or both.

Additionally, although FIG. 1 illustrates a two-layered die configuration, an example IC 100 may have a plurality of stacked die and the minimum height 114, loop height 116, and maximum height 118 may apply to any bond wire of the IC 100. In another example, the base measurement of minimum height 114, loop height 116, and maximum height 118 of the bond wires may be measured from the pads 103 (e.g, the minimum loop height is the distance from the surface of the pads 103 to the upper surface of the first die 114, etc.).

FIG. 2 illustrates an example stacked IC 200 with an overhanging edge. The IC 200 includes a substrate 202 with a plurality of pads 203 for bonding. The substrate may be implemented by any material that can accept the first die by any attaching technique (e.g., eutectic bond, epoxy, epoxy paste, solder, etc.). The pads 203 of the illustrated example are regions that allow bonding of wire bonds, die, and other elements associated with the IC 200.

In the example of FIG. 2, a first die 204 is attached to the substrate 202. After attaching the die to the substrate, the bond wires 206 are placed from the top of the first die 204 to at least some of the pads 203. After the first die 204 is attached, a spacer 208 is applied on top of the first die 204. The second die 210 is then attached to the top of the spacer 208 using any technique. Once the second die is attached, the bond wires 212 are connected to couple the top of the second die 210 to at least some of the pads 203.

In the example of FIG. 2, a support element 214 is positioned between the substrate 203 and the overhanging portion 201 of the die 203. The support element 214 may be made of a rigid material to prevent the second die 210 from bending down any further. For example, the support element 214 may be made of a stack of gold bumps, a rigid material (e.g., a metal, a metal alloy, etc.), a pseudo-elastic material such as a shape memory alloy (e.g., Nitinol, etc.), or a specialized material such as a polymer that is initially elastic but becomes rigid and inelastic after being heated to a specific temperature. The support element 214 may also be of any shape to support the die. For example, the vertical profile of the support element 214 may be circular, rectangular, triangular, or hexagonal. In some examples, the support element may be a cylindrical column.

In the example of FIG. 2, to protect the bond wires 206, the support element 214 is taller than the loop height 216 of the bond wires 206. In addition, to allow placement of the second die 210, the support element 214 is shorter than the maximum height 118 of the bond wires 206. However, in some examples, the support element 214 is shorter than the loop height 116 and still protects the bond wire 206 from contacting the bottom surface of the second die 210. In such examples, when the upper die bends due to a downward force, the degree a point on the upper die bends depends on the radial location of that point. In other words, the distance a point on the die bends downward depends on the distance the point is from the bending point 222, which may be located at the edge of the spacer 208. As illustrated in FIG. 2, the peak of the bond wire 206 may not be directly below the edge of the second die 210 and, in addition, the support element 214 may not be placed at the peak of the bond wire 206. Thus, a support element 214 shorter than the bond wire loop height 116 may then be placed below the second die 210 to prevent the second die 210 from contacting the bond wires 206.

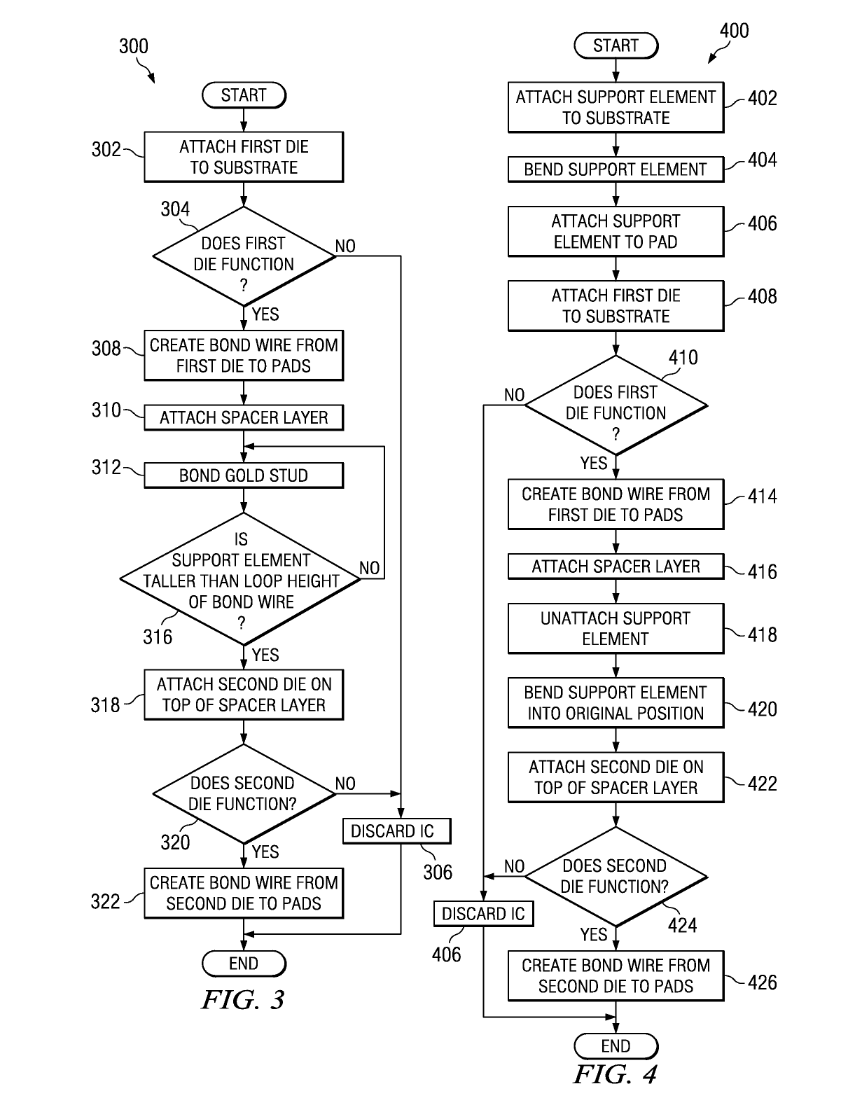

FIGS. 3, 4, and 5 illustrate example methods to create an integrated circuit with one or more support elements 214. Though FIGS. 3, 4, and 5 illustrate one support element placed in a stacked die configuration, the example methods may be used to place one or more support elements 214 anywhere along one or more overhanging edges of a die. For example, a support element 214 may be placed near each corner of each overhanging edge of the second die 210. Furthermore, additional support elements 214 may be placed along the overhanging edge to provide additional support for the second die 210. Any of the following processes may be used to assemble an IC such as the IC 200 shown in FIG. 2.

In the example of FIG. 3, the example process 300 begins by attaching a first die 204 onto the substrate 202 (block 302). After attaching the first die 204, the die is probed via a probe tester to see if the first die 204 functions (block 304). If the first die 204 is not functional, the IC 200 is discarded (block 306) and the example process 300 ends. If the first die 204 is functional, the bond wires 206 are placed between pads 203 and the top of first die 204 (block 308). After all wire bonds 206 are placed, a spacer 208 is attached to the top of the first die 204 (block 310). As described above, the spacer 208 creates a space between the stacked die to have space for the wire bonds 206.

After the spacer 208 is attached, one or more stacking gold studs 350 are placed on the substrate 202 near an edge or a corner of the overhang region of the second die (block 312). In the example process 300, the gold stud 350 forms the support element 214. Gold studs 350 are stacked on top of one another until a desired height is achieved for the support element. Thus, if the support element 214 is not taller than the loop height 216 of the bond wire 206 (block 316), the example process 300 returns to block 312 to place another gold stud on top of the support element 214.

When the support element 214 is taller than, for example, the loop height 216 of the bond wire 206 (block 316), the second die 210 is attached to the spacer 208 (block 318). After attaching the second die 210, the second die 210 is probed via a probe tester to determine if the second die 210 is functional (block 320). If the second die 210 is not functional, the IC 200 is discarded (block 306) and the example process 300 ends. If the second die 210 is functional, the wire bonds 212 are placed between bond pads 203 and the top of the second die 210 (block 322). After the wire bonding is complete, the example process 300 ends.

FIG. 4 illustrates another example process 400 to create an integrated circuit with one or more support elements 214. Initially, support elements 214 are placed on the substrate 202 (block 402). The support elements may be made of any material that is pseudo-elastic (e.g., a shape memory alloy such as Nitinol, etc.). Initially, the support elements 214 are placed substantially near the corner of an overhanging edge of the second die 210. The top portion of the support elements 214 are bent over (block 404) and attached to their respective pads 203 on the substrate 202 (block 406). The support elements 214 may be attached by, for example, solder. When the support elements 214 are bent over, they do not unduly obstruct the operation of the assembly tools associated with the example process 400 (e.g., wire bonder, die bonder, die attacher, probe tester, etc.).

In some examples, to attach the top of the support elements 214, the substrate 202 is heated to a temperature sufficient to melt a solder alloy. The tops of support elements 214 are then bent over and attached to their respective pads 203 via a solder alloy. After the support elements 214 are attached to the pads 203, the first die 204 is attached to the substrate 202 via a pad 203 (block 408). Of course, the first die 204 could alternative be placed on the substrate 202 before the support elements 214. After attaching the first die 204, the first die 204 is probed via a probe tester to see if the first die 204 is functional (block 410). If the first die 204 is not functional, the IC 200 is discarded (block 412) and the example process 400 ends. If the first die 204 is functional, the wire bonds 206 are placed between pads 203 and the top of first die 204 (block 414). After all wire bonds 206 are placed, a spacer 208 is attached to the top of the first die 204 (block 416).

After the spacer 208 is attached to the top of the first die 204, the support elements 214 are unattached from the pads 203 (block 418). In some examples, the substrate 202 is heated to a temperature to melt the solder alloy and unattach the support elements 214. In the example of FIG. 3, once unattached, the support elements 214 return to their original shapes (block 420). After the support elements 214 substantially return to their original shapes, the second die 210 is attached to the spacer 208 (block 422). Next, the second die 210 is probed via a probe tester to determine if the second die 210 is functional (block 424). If the first die is not functional, the IC 200 is discarded (block 412) and the example process 400 ends. If the second die 210 is functional, the wire bonds 212 are placed between the pads 203 and the top of second die 210 (block 426). After the placing the wire bonds 212, the example process 400 ends.

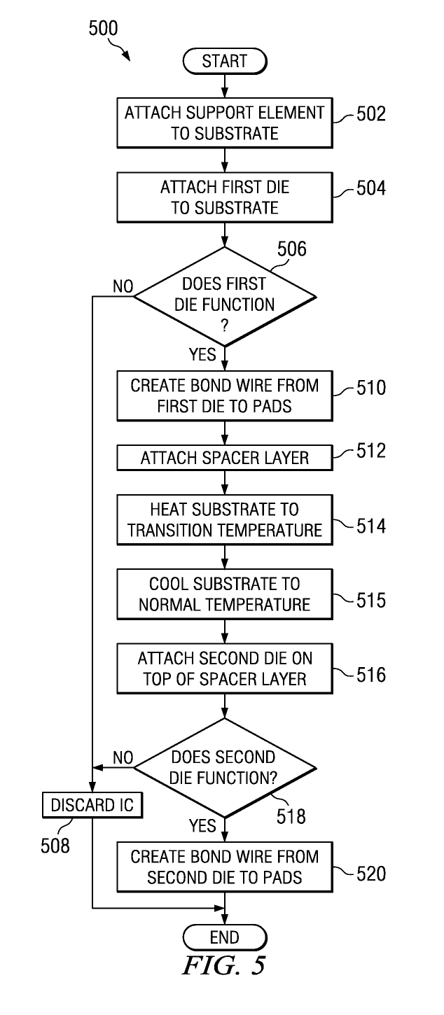

FIG. 5 illustrates another example process 500 to create an integrated circuit with support elements 214. Initially, support elements 214 are placed on the substrate 202 (block 502). The support elements 214 are initially an elastic material so that the support elements 214 do not unduly obstruct the operation of the assembly tools. The support elements 214 may be implemented by a material that, after being raised to a transition temperature, the support element becomes rigid and inelastic. One such material is a B-stage epoxy with a carbon-based rubber plasticizer (e.g., a 4-carbon or greater rubber such as butile, propyl, etc.). The plasticizer is a material with a low modulus of elasticity.

After the support elements 214 are attached, the first die 204 is attached to the substrate 202 via a pad 203 (block 504). After attaching the first die 204, the first die 204 is probed via a probe tester to determine if the first die 204 functions (block 506). If the first die is not functional, the IC 200 is discarded (block 508) and the example process 500 ends. If the first die 204 is functional, the wire bonds 206 are placed to couple the pads 203 and the top of first die 204 (block 510). After all wire bonds 206 are placed, a spacer 208 is attached to the top of the first die 204 (block 512). After the spacer 208 is attached to the top of the first die 204, the substrate 202 is heated to a temperature above the transition temperature of the support elements 214 (block 514).

Upon heating the support elements 214 to a transition temperature (e.g., 170° C.), the plasticizer crosslinks with the B-stage epoxy and increases the crosslink density, thus, reducing the elasticity of the material. In other words, by crosslinking the epoxy and the plasticizer and increasing the crosslink density, the material forming the support elements 214 becomes substantially rigid and inelastic. After heating the support element 214 to make the support elements 214 inelastic, the substrate 202 is returned to the normal temperature during assembly operations (block 516).

After the material of support elements 214 has become rigid, the second die 210 is attached to the spacer 208 (block 518). After attaching the second die 210, the second die 210 is probed via a probe tester to determine if the second die 210 is functional (block 520). If the first die is not functional, the IC 200 is discarded (block 508) and the example process 500 ends. If the second die 210 is functional, the wire bonds 212 are placed between bond pads 203 and the top of second die 210 (block 522). After the placing the wire bonds 212, the example process 500 ends.

Although certain articles of manufacture, methods, and apparatus have been disclosed, the scope of coverage of this patent is not limited thereto. On the contrary, this patent covers all apparatus, methods and articles of manufacture fairly falling within the scope of the appended claims either literally or under the doctrine of equivalents.

What is claimed is:

1. A method to support an overhang region in an integrated circuit, comprising:
bonding a first die onto a substrate;
placing a support element on the substrate; and
bonding a second die above the first die, wherein the second die overhangs at least one edge of the first die and the support element is positioned to limit bending of the second die.

2. The method as defined in claim 1, wherein the support element is substantially elastic.

3. The method as defined in claim 2, wherein the support element is formed by an epoxy and a plasticizer.

4. The method as defined in claim 2, further comprising heating the substrate to make the support element substantially inelastic.

5. The method as defined in claim 4, wherein heating the substrate to make the support element substantially inelastic is before bonding the second die above the first die.

6. The method as defined in claim 1, wherein the support element is formed by a shape memory alloy.

7. The method as defined in claim 6, wherein the support element is arranged to allow the first die to be bonded to a pad on the substrate.

8. The method as defined in claim 7, wherein the support element is bent over and a top of the support element is bonded a pad on the substrate.

9. A method as defined in claim 8, wherein the support element substantially returns to its original shape prior to bonding before bonding a second die above the first die.

10. The method as defined in claim 1, wherein placing the support element on the substrate comprises stacking a plurality of gold stud bumps on the substrate.

11. The method as defined in claim 1, wherein the support element is taller than the first die and the space isolated between a top of the support element and the second die when the second die is not bent.

12. The method as defined in claim 1, wherein the support element is beneath at least one corner of the one edge of the second die that overhangs the first die.

13. An integrated circuit, comprising:
a substrate;
a first die;
a second die above the first die, the second die having at least one edge that overhangs the first die; and
a support element positioned beneath the overhang and separated from the second die to prevent the second die from contacting an interconnect element.

14. The integrated circuit as defined in claim 11, wherein the support element comprises at least two gold bumps arranged in a stacked configuration.

15. The integrated circuit as defined in claim 11, wherein the support element is formed from a shape memory alloy.

16. The integrated circuit as defined in claim 11, wherein the support element is elastic.

17. The integrated circuit as defined in claim 16, wherein the support element is formed from an epoxy and a plasticizer.

18. The integrated circuit as defined in claim 16, wherein the support element becomes inelastic when heated to a transition temperature.

19. The integrated circuit as defined in claim 11, wherein the support element is placed substantially near a corner of the at least one edge of second die.

20. The integrated circuit as defined in claim 11, wherein the support element is taller than a loop height of the interconnect element.

21. The integrated circuit as defined in claim 11, wherein the support element is shorter than a peak height of the interconnect element.

22. The integrated circuit as defined in claim 11, wherein the interconnect element is a bond wire.
